(19) United States
(12) Patent Application Publication
(10) Pub. No.: US 2020/0075685 A1
(43) Pub. Date: Mar. 5, 2020

(54) DISPLAY PANEL AND MANUFACTURING METHOD THEREOF, AND DISPLAY DEVICE

(71) Applicants: Ordos Yuansheng Optoelectronics Co., Ltd., Inner Mongolia (CN); BOE Technology Group Co., Ltd., Beijing (CN)

(72) Inventors: Zhiliang JIANG, Beijing (CN); Kai ZHANG, Beijing (CN); Yangpeng WANG, Beijing (CN); Guoqiang TANG, Beijing (CN); Jianjun WU, Beijing (CN)

(21) Appl. No.: 16/610,636

(22) PCT Filed: Apr. 18, 2019
(86) PCT No.: PCT/CN2019/083296

§ 371 Date: Nov. 4, 2019

(30) Foreign Application Priority Data
Apr. 28, 2018 (CN) 201810402120.2

(51) Int. Cl. H01L 27/32

(52) U.S. Cl. CPC H01L 27/323

(57) ABSTRACT

The present disclosure discloses a display panel and a manufacturing method thereof, and a display device. The display panel includes: a second substrate and a first substrate which are oppositely disposed, and a touch circuit located on the side, facing the second substrate, of the first substrate. The touch circuit includes a first contact portion, and a plurality of contact electrodes are disposed on the side, facing the second substrate, of the first contact portion. The second substrate includes a second contact portion corresponding to the first contact portion. A plurality of contact pads are disposed on the side, facing the first substrate, of the second contact portion. The contact pads are in direct contact connection with the contact electrodes.

This disclosure is a National Stage of International Application No. PCT/CN2019/083296, filed on Apr. 18, 2019, which claims priority to China Patent Disclosure No. 201810402120.2, filed on Apr. 28, 2018 and entitled “Display Panel and Manufacturing Method Thereof, and Display Device”, both of which are hereby incorporated by reference in their entireties.

### FIELD

The present disclosure relates to the technical field of displaying, and more particularly relates to a display panel and a manufacturing method thereof, and a display device.

### BACKGROUND

In recent years, Organic Light-Emitting Diode (OLED) displays have become very popular emerging flat display products at home and abroad thanks to the advantages of self-illumination, wide viewing angle, short response time, high luminous efficiency, wide color gamut, low working voltage and the like.

### SUMMARY

Some embodiments of the present disclosure provide a display panel, including: a second substrate and a first substrate which are oppositely disposed, and a touch circuit located on the side, facing the second substrate, of the first substrate.

The touch circuit includes a first contact portion, and a plurality of contact electrodes are disposed on the side, facing the second substrate, of the first contact portion.

The second substrate includes a second contact portion corresponding to the first contact portion. A plurality of contact pads are disposed on the side, facing the first substrate, of the second contact portion. The contact pads are in direct contact connection with the contact electrodes.

In one possible implementation mode, in the above display panel provided by some embodiments of the present disclosure, the touch circuit further includes a third contact portion located outside the first contact portion.

The display panel further includes sealants located on the side, facing the second substrate, of the third contact portion, and a support structure located on the side, facing the first substrate, of the first contact portion.

An orthographic projection, on the first substrate, of the contact electrodes on the first contact portion is located inside an orthographic projection, on the first substrate, of the support structure.

In one possible implementation mode, in the above display panel provided by some embodiments of the present disclosure, a cross-sectional area of the support structure in a direction parallel to the first substrate is gradually decreased along a direction from the first substrate to the second substrate.

In one possible implementation mode, in the above display panel provided by some embodiments of the present disclosure, a plurality of protrusion structures are disposed on the surface, facing the touch circuit, of the support structure.

In one possible implementation mode, in the above display panel provided by some embodiments of the present disclosure, a cross-sectional area of the protrusion structures in the direction parallel to the first substrate is gradually decreased along the direction from the first substrate to the second substrate.

In one possible implementation mode, in the above display panel provided by some embodiments of the present disclosure, the dimension of the support structure is less than or equal to that of the sealants along the direction from the first substrate to the second substrate.

In one possible implementation mode, in the display panel provided by some embodiments of the present disclosure, a material of the support structure includes polyimide.

Some embodiments of the present disclosure further provide a manufacturing method of the above display panel, including:

forming each film layer of a touch circuit on a first substrate;

forming a plurality of contact electrodes on a first contact portion of the touch circuit;

forming a plurality of contact pads on a second contact portion of a second substrate; and

fitting the side, facing the contact electrodes, of the first substrate to the side, facing the contact pads, of the second substrate to achieve direct contact between the contact pads and the contact electrodes.

In one possible implementation mode, in the above manufacturing method provided by some embodiments of the present disclosure, before forming each film layer of the touch circuit on the first substrate, the manufacturing method further includes:

forming a support structure on the first substrate.

In addition, some embodiments of the present disclosure further provide a display device, including the above display panel.

### BRIEF DESCRIPTION OF THE DRAWINGS

FIG. 1 is a structural schematic diagram I of a display panel provided by some embodiments of the present disclosure;

FIG. 2 is a partially enlarged diagram within a dotted box A in FIG. 1;

FIG. 3a is a two-dimensional schematic diagram of a first contact portion;

FIG. 3b is a two-dimensional schematic diagram of a second contact portion;

FIG. 4 is a structural schematic diagram II of a display panel provided by some embodiments of the present disclosure;

FIG. 5 is a flow chart of a manufacturing method of the above display panel provided by some embodiments of the present disclosure; and

FIGS. 6a to 6e are structural schematic diagrams corresponding to the above manufacturing method in the embodiment of the present disclosure.

### DETAILED DESCRIPTION OF THE EMBODIMENTS

Embodiments of the present disclosure provide a display panel and a manufacturing method thereof, and a display device in order to solve the problem of high difficulty of a binding process of an on cell touch structure in the related art.

In the related art, a rigid Active-Matrix Organic Light Emitting Diode (AMOLED) touch screen is mainly of an on cell touch structure, that is, a Touch Screen Panel (TSP) is manufactured on a surface of packaging glass. This on cell touch structure has the advantages of high sensitivity, high impact resistance, high fall-off resistance and the like.

For this on cell touch structure, in order to connect a touch electrode on the TSP to a control chip on an OLED base substrate, contact electrodes on the TSP need to bonding with contact pads on the OLED base substrate by using a wire to realize a touch function. However, the binding process is relatively difficult, and the problems of poor touch effect and the like are caused by easy fall-off of the wire in the process.

The specific implementation modes of a display panel and a manufacturing method thereof, and a display device which are provided by the embodiments of the present disclosure are described in detail below in conjunction with the accompanying drawings. The thickness and shape of each film layer in the drawings do not reflect real scales, and are merely to illustrate the contents of the present disclosure.

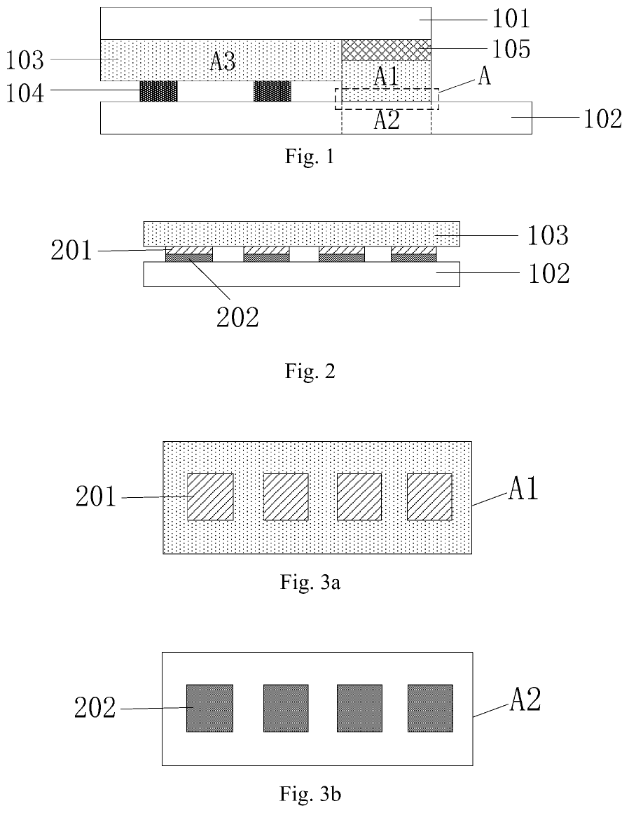

On a first aspect, some embodiments of the present disclosure provide a display panel, as shown in FIG. 1, including: a first substrate 101 and a second substrate 102 which are oppositely disposed, and a touch circuit 103 located on the side, facing the second substrate 102, of the first substrate 101.

The touch circuit 103 includes a first contact portion A1, and a plurality of contact electrodes (not shown in FIG. 1) are disposed on the side, facing the second substrate 102, of the first contact portion A1.

The second substrate 102 includes a second contact portion A2 corresponding to the first contact portion A1, that is, the second contact portion A2 at least partially overlaps the first contact portion A1. A plurality of contact pads (not shown in FIG. 1) are disposed on the side, facing the first substrate 101, of the second contact portion. The contact pads are in direct contact connection with the contact electrodes.

In the display panel provided by the embodiment of the present disclosure, the touch circuit is disposed on the side, facing the second substrate, of the first substrate, that is, the touch circuit is disposed between the first substrate and the second substrate. By arranging the contact electrodes on the side, facing the second substrate, of the first contact portion of the touch circuit and arranging the contact pads on the side, facing the first substrate, of the second contact portion of the second substrate, the contact electrodes on the touch circuit may be in direct contact connection with the contact pads on the second substrate, so that during manufacturing, the first substrate and the second substrate only need to be aligned and fitted together without a bonding process, thereby simplifying the manufacturing process, avoiding a phenomenon of poor contact between the contact electrodes and the contact pads and enhancing the touch effect.

As shown in FIG. 1, in some embodiments of the present disclosure, the first substrate 101 may be a base substrate, and the second substrate 102 may be a packaging substrate. An integrated chip may be disposed on the first substrate 101. The touch circuit 103 is disposed between the second substrate 102 and the first substrate 101, that is, an in cell touch structure is used. The contact electrodes on the touch circuit 103 are in direct contact connection with the corresponding contact pads on the second substrate 102 to realize connection between the touch circuit 103 and the integrated chip, so that the contact electrodes on the touch circuit 103 can be bound to the second substrate 102 without a wire. During manufacturing, each film layer of the touch circuit 103 may be manufactured at first on the first substrate 101, and then the first substrate 101 is flipped 180 degrees to be aligned with and fitted to the second substrate 102. Compared with the on cell touch structure manufactured by the binding process, the display panel provided by the embodiment of the present disclosure has the advantages that the manufacturing process is simpler, the phenomenon of the poor contact between the contact electrodes and the contact pads is not easy to occur, and the touch effect and the reliability of the display panel are improved.

Exemplarily, both the contact electrodes and the contact pads may be of metal structures, so as to enhance the electric contact effect.

During specific implementation, the display panel may be an Organic Light-Emitting Diode (OLED) display panel, or may be other types of display panels, and it is not limited herein. The second substrate may generally include a luminous layer, an anode layer, a cathode layer and other structures. In addition, referring to FIG. 1, the second substrate 102 may also include a frame region (e.g., an uncovered region on the right side in FIG. 1) in addition to a region covered by the first substrate 101. Structures such as an Integrated Circuit (IC) and a flexible printed circuit board may be disposed in the frame region. The touch circuit may be a Touch Screen Panel (TSP), or may be other structures having a touch function, and it is not limited herein.

FIG. 2 is a partially enlarged diagram within a dotted box Ain FIG. 1. FIGS. 3a and 3b are two-dimensional structural schematic diagrams of a first contact portion and a second contact portion. As shown in FIG. 2, a plurality of contact electrodes 201 are disposed on the side, facing the second substrate 102, of the touch circuit 103, and a plurality of contact pads 202 are disposed on the side, facing the first substrate 101, of the second substrate 102. The contact electrodes 201 are in direct contact connection with the contact pads 202. During specific implementation, the contact electrodes 201 may be in one-to-one correspondence to the contact pads 202, or the contact electrodes 201 may be set to be more or less than the contact pads 202. Orthographic projections, on the second substrate 102, of the contact electrodes 201 and orthographic projections, on the second substrate 102, of the contact pads 202 have overlap regions, and may either completely overlap or partially overlap, as long as the contact electrodes and the corresponding contact pads are ensured to be in direct contact connection after being aligned and fitted. For example, the orthographic projections of the contact electrodes may be located inside the orthographic projections of the corresponding contact pads, or the orthographic projections of the contact pads are located inside the orthographic projections of the corresponding contact electrodes, or the contact electrodes and the corresponding contact pads are completely the same in size and have completely overlapping orthographic projections.

Exemplarily, as shown in FIG. 3a, the first contact portion A1 of the touch circuit 103 may include one row of contact electrodes 201, and as shown in FIG. 3b, the second contact portion A2 of the second substrate 102 may include one row of contact pads 202. In addition, the arrangement modes of the contact electrodes and the contact pads may also be set according to actual structures on the touch circuit and the second substrate, and are not limited herein. In FIGS. 3a and 3b, only square contact electrodes and square contact pads are illustrated. During specific implementation, the contact electrodes and the contact pads may also be of other shapes, such as trapezoid or triangle, and are not limited herein. In FIGS. 2, 3a and 3b, four contact electrodes and four contact pads are illustrated. During specific implementation, the number of contact electrodes and the number of contact pads may be set as actually required, and are not limited here.

Further, in the above display panel provided by some embodiments of the present disclosure, as shown in FIG. 1, the touch circuit 103 further includes a third contact portion A3 located outside the first contact portion A1. The display panel further includes: sealants 104 located on the side, facing the second substrate 102, of the third contact portion A3, and a support structure 105 located on the side, facing the first substrate 101, of the touch circuit 103. Optionally, the support structure 105 is located on the side, facing the first substrate 101, of the first contact portion A1. The orthographic projection, on the first substrate 101, of each of the contact electrodes on the first contact portion A1 is located inside an orthographic projection, on the first substrate 101, of the support structure 105. Orthographic projections, on the first substrate 101, of the sealants 104 and the orthographic projection, on the first substrate 101, of the support structure 105 do not overlap.

Referring to FIG. 1, in the process of manufacturing the display panel, the touch circuit 103 needs to be formed on the first substrate 101 at first. After the first substrate 101 is flipped 180 degrees, the first substrate 101 is fitted to the second substrate 102 by the sealants 104. The sealants 104 have a certain thickness (about 5 μm). In order to enhance the contact effect between the contact electrodes and the corresponding contact pads and avoid the phenomenon of poor contact, the support structure 105 is disposed between the first substrate 102 and the touch circuit 103, and each of the contact electrodes on the first contact portion A1 is in a coverage range of the support structure 105, so that the support structure 105 may jack up the position where each of the contact electrodes is placed to allow the surfaces of the sides, away from the first substrate 101, of the contact electrodes to be approximately flush with the surfaces of the sides, away from the first substrate 101, of the sealants 104. Therefore, after the first substrate 101 is flipped 180 degrees, the contact electrodes are closer to the contact pads on the second substrate 102, which ensures that the contact electrodes may be in direct contact connection with the corresponding contact pads.

As shown in FIG. 1, the sealants 104 are disposed on the side, facing the second substrate 102, of the touch circuit 103, and are located on the third contact portion A3, so that the sealants 104 may be avoided from covering the contact electrodes and affecting the contact between the contact electrodes and the corresponding contact pads. In addition, the support structure 105 is arranged to jack up each of the contact electrodes to allow the contact electrodes to be approximately flush with the surfaces of the sides, away from the first substrate 101, of the sealants 104. If the orthographic projections, on the first substrate 101, of the support structure 105 and the sealants 104 have overlap regions, protrusions may appear in the overlap regions, and the contact electrodes are possibly covered by the sealants 104, which may affect the contact effect between the contact electrodes and the contact pads. Therefore, the orthographic projections, on the first substrate 101, of the sealants 104 and the support structure 105 do not overlap.

In addition, during specific implementation, each of the contact electrodes on the first contact portion may also be jacked up by other methods. For example, each of contact electrodes may be jacked up by increasing the thickness of a certain film layer or a plurality of film layers at a corresponding position of the first contact portion in the process of manufacturing each film layer in the touch circuit, or support structures are disposed between the film layers of the touch circuit, and there is no limitation herein.

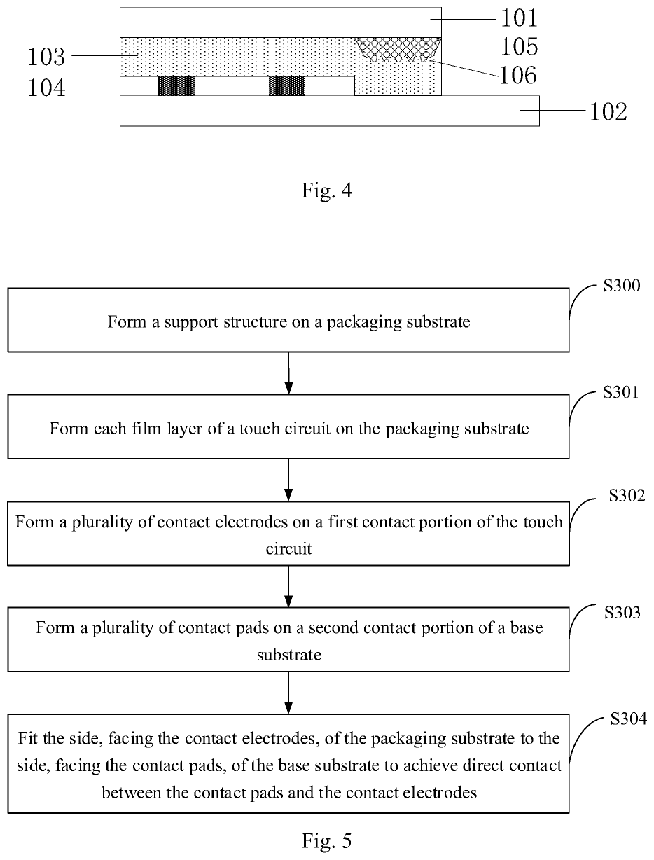

In actual application, in the above display panel provided by the embodiment of the present disclosure, as shown in FIG. 4, a cross-sectional area of the support structure 105 in a direction parallel to the first substrate 101 is gradually decreased along a direction (namely a direction from top to bottom in FIG. 4) from the first substrate 101 to the second substrate 102. That is, if the support structure 105 is closer to the first substrate 101, the cross-sectional area in the direction parallel to the first substrate 101 is larger. Exemplarily, at this time, the support structure 105 may have a trapezoidal cross section in a direction perpendicular to the first substrate 101. Then, in the process of manufacturing the display panel, after the support structure 105 is formed on the first substrate 101, each film layer of the touch circuit 103 may extend along the edge of the support structure 105 to form a film and is not easy to break, so that breakage of a metal line in the touch circuit 103 in the film forming process may be avoided. In actual application, the shape of the support structure 105 may also be set as actually required, such as a columnar structure. The shape of the support structure 105 is not limited herein.

Further, in the above display panel provided by the embodiment of the present disclosure, as shown in FIG. 4, a plurality of protrusion structures 106 are disposed on the surface of the side, facing the touch circuit 103, of the support structure 105. The protrusion structures 106 are micro structures. Exemplarily, if the support structure 105 is several microns in thickness, the protrusion structures 106 may be dozens of nanometers to several hundreds of nanometers in thickness. In the manufacturing process, the plurality of protrusion structures 106 may be integrated with the support structure 105, or the support structure 105 and the plurality of protrusion structures 106 are manufactured in order. The manufacturing method of the protrusion structures 106 is not limited herein. By arranging the plurality of protrusion structures 106 on the surface of the support structure 105, after the support structure 105 and the plurality of protrusion structures 106 are manufactured, the protrusion structures 106 may play a certain buffer role during the manufacturing of each film layer of the touch circuit 103, so as to further avoid the metal line of the touch circuit 103 from being broken in hard contact.

Further, in the above display panel provided by some embodiments of the present disclosure, as shown in FIG. 4, a cross-sectional area of each of the protrusion structures 106 in the direction parallel to the first substrate 101 is gradually decreased along the direction (namely the direction from top to bottom in FIG. 4) from the first substrate 101 to the second substrate 102. That is, if the protrusion structures 106 are closer to the support structure 105, the cross-sectional area in the direction parallel to the first substrate 101 is larger. Exemplarily, the protrusion structures 106 may have trapezoidal cross sections in the direction perpendicular to the first substrate 101. Therefore, in the manufacturing process, each film layer of the touch circuit 103 may extend along the edge of the protrusion structure 106 to form a film, so that the breakage of the metal line in the touch circuit 103 in the film forming process may be further avoided. During specific implementation, the shapes of the protrusion structures 106 may also be set as actually required, and are not limited herein.

During specific implementation, in the above display panel provided by the embodiment of the present disclosure, the thickness of the support structure may be less than or equal to that of the sealant. Referring to FIGS. 1 and 4, the support structure 105 are configured to jack up the respective contact electrodes on the first contact portion A1 to allow the contact electrodes to be flush with the surfaces of the sides, close to the second substrate 102, of the sealants 104, and the support structure 105 and the sealants 104 are respectively located on two sides of the touch circuit 103. If the touch circuit 103 has a consistent thickness at all positions, the thickness (namely the length along the direction from the first substrate 101 to the second substrate 102) of the support structure 105 may be equal to the thickness (namely the length along the direction from the first substrate 101 to the second substrate 102) of the sealants 104, and the thickness of the support structure 105 may also be adjusted according to the thicknesses of each film layer in the touch circuit 103. If the thickness of the position, where the first contact portion A1 is placed, on the touch circuit 103 is greater than the thicknesses of other positions, the thickness of the support structure 105 may be less than that of the sealants 104. In actual application, the thickness of the sealants 104 is about 5 μm, so that the thickness of the support structure 105 may be less than or equal to 5 μm. In addition, in order to avoid overlapping of the orthographic projections, on the first substrate 101, of the support structure 105 and the sealants 104, the support structure 105 may be disposed at a position that is a certain distance away from the sealants 104. Exemplarily, a horizontal distance (a distance along the direction parallel to the first substrate 101) between the support structure 105 and the closest sealant 104 is longer than 200 μm.

Optionally, in the display panel provided by some embodiments of the present disclosure, a material of the support structure includes polyimide (PI). Other materials may also be used. For example, an insulating material such as a polymer may also be used. The material of the support structure is not limited herein.

On a second aspect, based on the same disclosure idea, some embodiments of the present disclosure provide a manufacturing method of the above display panel. The principle of the manufacturing method for solving problems is similar to that of the display panel, so that the implementation of the manufacturing method may refer to the implementation of the display panel, and repeated descriptions will be omitted.

The manufacturing method of the display panel, provided by some embodiments of the present disclosure, as shown in FIG. 5, includes:

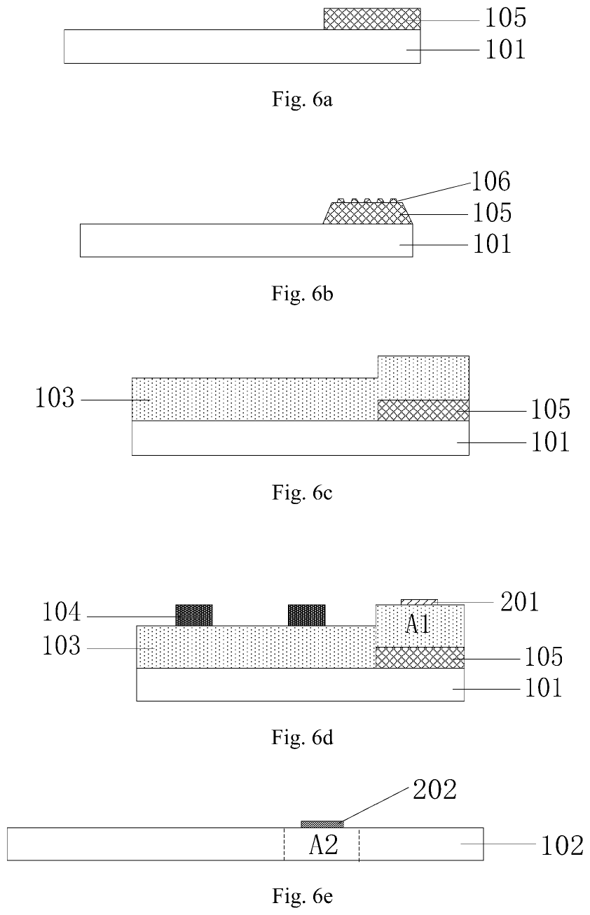

S301, film layers of a touch circuit 103 are formed on a first substrate 101, as shown in FIG. 6c;

S302, a plurality of contact electrodes 201 are formed on a first contact portion A1 of the touch circuit 103, as shown in FIG. 6d;

S303, a plurality of contact pads 202 are formed on a second contact portion A2 of a second substrate 102, as shown in FIGS. 6e; and

S304, the side, facing the contact electrodes 201, of the first substrate 101 is fitted to the side, facing the contact pads 202, of the second substrate 102 to achieve direct contact between the contact pads 202 and the contact electrodes 201, so as to obtain the structure as shown in FIG. 1.

According to the manufacturing method provided by some embodiments of the present disclosure, each film layer of the touch circuit is manufactured on the first substrate, and the plurality of contact electrodes are manufactured on the surface of the touch circuit, and the plurality of contact pads corresponding to the contact electrodes are manufactured on the second substrate, and then the first substrate is flipped 180 degrees, and the side, facing the contact electrodes, of the first substrate is aligned and fitted to the second substrate to achieve the direct contact connection between the contact pads and the corresponding contact electrodes, so that no binding process is needed, and the manufacturing process is simplified. Furthermore, the phenomenon of poor contact between the contact electrodes and the contact pads does not easily occur, and the touch effect of the display panel is enhanced.

Further, before the above step S301, the manufacturing method provided by the embodiment of the present disclosure, as shown in FIG. 5, may further include:

S300, a support structure 105 is formed on the first substrate 101, as shown in FIG. 6a.

During specific implementation, the support structure may be manufactured by exposure, development, etching and other processes. The support structure may be made of a polyimide (PI) material. In addition, the support structure may also be made of other materials or by other processes, and there is no limitation here. As shown in FIG. 6b, in order to avoid breakage of a metal line in the touch circuit due to hard contact in the step S301, a plurality of protrusion structures 106 that play a buffer role may also be formed on the surface of the support structure 105. In addition, cross-sectional areas of the support structure 105 and the protrusion structures 106 in a direction parallel to the first substrate 101 are gradually decreased along a direction (such as a direction from bottom to top in the figure) away from the first substrate 101, that is, the cross section in a direction perpendicular to the first substrate 101 may be trapezoidal. Of course, the cross section of the support structure 105 in the direction perpendicular to the first substrate 101 may also be of a columnar structure as shown in FIG. 6a, and it is not limited herein.

As shown in FIG. 6c, in the above step S301, each film layer of the touch circuit 103 is formed on the first substrate 101 with the support structure 105, so that the touch circuit 103 at the position where the support structure 105 is placed is jacked up. As shown in FIG. 6d, in the above step S302, the plurality of contact electrodes 201 are formed at the position, jacked up by the support structure 105, on the surface of the touch circuit 103, and sealants 104 are manufactured at positions that do not overlap the support structure 105. The surfaces of the sealants 104 may be optionally flush with the surfaces of the contact electrodes 201. As shown in FIG. 6e, in the above step S303, the plurality of contact pads 202 are formed on the second contact portion A2 of the second substrate 102, and the second contact portion A2 corresponds to the first contact portion on the first substrate, and the contact pads 202 correspond to the contact electrodes on the first substrate. In the above step S304, after the first substrate 101 obtained in FIG. 6 is flipped 180 degrees and is aligned with and fitted to the second substrate 102 as shown in FIG. 6e, the contact electrodes 201 and the corresponding contact pads 202 are in direct contact connection, thereby obtaining the display panel as shown in FIG. 1.

On a third aspect, based on the same disclosure idea, some embodiments of the present disclosure provides a display device, including the above display panel. The display device may be applied to any product or component having a display function, such as a mobile phone, a tablet computer, a TV set, a display, a notebook computer, a digital photo frame and a navigator. The principle of the display device for solving problems is similar to that of the display panel, so that the implementation of the display device may refer to the implementation of the display panel, and repeated descriptions will be omitted.

In the display panel and the manufacturing method thereof, and the display device which are provided by the embodiments of the present disclosure, the touch circuit is disposed on the side, facing the second substrate, of the first substrate, that is, the touch circuit is disposed between the first substrate and the second substrate. By arranging the contact electrodes on the side, facing the second substrate, of the first contact portion of the touch circuit and arranging the contact pads on the side, facing the first substrate, of the second contact portion of the second substrate, the contact electrodes on the touch circuit may be in direct contact connection with the contact pads on the second substrate, so that in the manufacturing process, the first substrate and the second substrate only need to be aligned and fitted together without a binding process, thereby simplifying the manufacturing process, avoiding a phenomenon of poor contact between the contact electrodes and the contact pads and enhancing the touch effect.

Obviously, those skilled in the art can make various changes and modifications to the present disclosure without departing from the spirit and scope of the present disclosure. Therefore, if these changes and modifications of the present disclosure fall within the scope of the claims of the present disclosure and equivalent technologies of the present disclosure, the present disclosure is intended to include these changes and modifications.

1. A display panel, comprising: a first substrate and a second substrate which are oppositely disposed, and a touch circuit located on a side, facing the second substrate, of the first substrate, wherein
the touch circuit comprises a first contact portion, and a plurality of contact electrodes are disposed on a side, facing the second substrate, of the first contact portion;
the second substrate comprises a second contact portion corresponding to the first contact portion; a plurality of contact pads are disposed on a side, facing the first substrate, of the second contact portion; and the contact pads are in direct contact connection with the contact electrodes.

2. The display panel according to claim 1, wherein
the touch circuit further comprises a third contact portion located outside the first contact portion;
the display panel further comprises sealants located on a side, facing the second substrate, of the third contact portion, and a support structure located on a side, facing the first substrate, of the first contact portion;
an orthographic projection, on the first substrate, of the contact electrodes on the first contact portion is located inside an orthographic projection, on the first substrate, of the support structure.

3. The display panel according to claim 2, wherein a cross-sectional area of the support structure in a direction parallel to the first substrate is gradually decreased along a direction from the first substrate to the second substrate.

4. The display panel according to claim 2, wherein a plurality of protrusion structures are disposed on a surface of a side, facing the touch circuit, of the support structure.

5. The display panel according to claim 4, wherein a cross-sectional area of the protrusion structures in a direction parallel to the first substrate is gradually decreased along a direction from the first substrate to the second substrate.

6. The display panel according to claim 2, wherein a dimension of the support structure is less than or equal to that of the sealants along a direction from the first substrate to the second substrate.

7. The display panel according to claim 2, wherein a material of the support structure comprises a polyimide.

8. A manufacturing method of the display panel according to claim 1, comprising:
forming film layers of a touch circuit on a first substrate;
forming a plurality of contact electrodes on a first contact portion of the touch circuit;
forming a plurality of contact pads on a second contact portion of a second substrate; and
fitting a side, facing the contact electrodes, of the first substrate to a side, facing the contact pads, of the second substrate to achieve direct contact between the contact pads and the contact electrodes.

9. The manufacturing method according to claim 8, wherein before forming the film layers of the touch circuit on the first substrate, the manufacturing method further comprises:
forming a support structure on the first substrate.

10. A display device, comprising: the display panel according to claim 1.

11. The display device according to claim 10, wherein
the touch circuit further comprises a third contact portion located outside the first contact portion;
the display panel further comprises sealants located on a side, facing the second substrate, of the third contact portion, and a support structure located on a side, facing the first substrate, of the first contact portion;
an orthographic projection, on the first substrate, of the contact electrodes on the first contact portion is located inside an orthographic projection, on the first substrate, of the support structure.

12. The display device according to claim 11, wherein a cross-sectional area of the support structure in a direction parallel to the first substrate is gradually decreased along a direction from the first substrate to the second substrate.

13. The display device according to claim 11, wherein a plurality of protrusion structures are disposed on a surface of a side, facing the touch circuit, of the support structure.

14. The display device according to claim 13, wherein a cross-sectional area of the protrusion structures in a direction parallel to the first substrate is gradually decreased along a direction from the first substrate to the second substrate.

15. The display device according to claim 11, wherein a dimension of the support structure is less than or equal to that of the sealants along a direction from the first substrate to the second substrate.

16. The display device according to claim 11, wherein a material of the support structure comprises a polyimide.
